(19) United States
(12) Patent Application Publication
(10) Pub. No.: US 2008/0063784 A1
(43) Pub. Date: Mar. 13, 2008

(54) GLUE DISPENSING PROCESS

(75) Inventor: KUN-I YUAN, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/618,008

(22) Filed: Dec. 29, 2006

(30) Foreign Application Priority Data
Sep. 8, 2006 (CN) 200610062518.3

(51) Int. Cl. C23C 16/52; B05D 3/12; B05C 11/00

(52) U.S. Cl. 427/8; 427/240; 118/663; 118/668

(57) ABSTRACT

An exemplary glue dispensing process is provided. A lens module including a lens barrel and an annular spacer received in the lens barrel is provided. The lens module is rotated around a central axis of the lens barrel in a manner such that rotational speed of the lens module is variable in an initial stage and is essentially constant in a subsequent steady stage. Whether the rotational speed of the lens module is in the initial stage or the subsequent steady stage is then detected. A first operating pressure and a second operating pressure different from the first operating pressure are applied onto the glue to dispense the glue onto the spacer during one revolution of the lens module, corresponding to both the rotational speed of the initial stage and the subsequent steady stage.

### BACKGROUND

1. Technical Field

The present invention relates generally to glue, adhesive, or the like dispensing processes.

2. Description of Related Art

Nowadays, lens modules are widely employed in camera systems and mobile phones for image capturing. Generally, a lens module includes a lens barrel, at least a lens group, a spacer, and a filter (e.g., an IR-cut filter). The lens group, the spacer and the filter are received in the lens barrel and arranged along an optical axis thereof one after the other from an object side to an image side of the lens module.

In assembly, a glue dispenser for dispensing glue is provided. The glue dispenser includes a nozzle, a container, and a pressure-applying member slidably fitted into the container. The nozzle is communicated with the container. The pressure-applying member is configured for applying a pressure on glue contained in the container in order to force the glue to flow out from the nozzle. The lens group and the spacer are firstly secured into the lens barrel, and then a bonding layer for bonding the filter to the spacer is formed on a pre-dispensing side of the spacer. The pre-dispensing side of the spacer (acting as a pre-dispending target) is located opposite to the lens group. The formation of the bonding layer actually is a product of a series of sub-steps. The lens barrel is placed/loaded on a rotating platform. The nozzle of the glue dispenser is positioned adjacent to the pre-dispensing side of the spacer. The rotating platform is actuated to rotate and thus the lens barrel positioned thereon undergoes a simultaneous rotary movement therewith, meanwhile glue contained in the container is forced to flow out from the nozzle and dispensed/distributed onto the pre-dispensing side of the spacer in order to form the bonding layer. After the formation of the bonding layer, the filter is bonded on the pre-dispensing side of the spacer and thus the lens module is completely assembled.

However, during the forming process of the bonding layer, in one aspect, as shown in FIG. 4, a rotary movement of the lens barrel generally includes an initial stage and a steady stage. In the initial stage, a rotational speed of the rotary movement is gradually increased; and in the steady stage, the rotational speed of the rotary movement is essentially constant. In another aspect, as shown in FIG. 5, a constant pressure is applied to the glue contained in the glue container via the pressure-applying member in both the initial stage and the steady stage, i.e., an amount of the glue flowing out from the nozzle in per unit time is constant. As a result, the glue dispensed/distributed on the pre-dispensing side of the spacer is non-uniform, due to the cooperative work of the fixed amount of the glue flowing out from the nozzle in per unit time and the variable rotational speed associated with the rotary movement, which will degrade the quality of the resultant lens module in some degrees. More specifically, if an amount of the dispensed glue in per unit area of the spacer is less than that required, the filter will not be firmly bonded on the spacer; whereas if the amount of the dispensed glue in per unit area of the spacer is excessive, the filter may be contaminated by the excessive glue.

Therefore, what is needed is to provide a glue dispensing process, in order to achieve a highly uniform glue distribution on a pre-dispensing target.

### SUMMARY

A preferred embodiment provides a dispensing process for glue/adhesive. The dispensing process includes the following steps of:
providing a lens module including a lens barrel and an annular spacer received in the lens barrel;
rotating the lens module around a central axis of the lens barrel in a manner such that a rotational speed of the lens module is variable in an initial stage and is essentially constant in a subsequent steady stage;
detecting whether the rotational speed of the lens module is in the initial stage or the subsequent steady stage;
applying a first operating pressure onto the glue to dispense the glue onto the spacer during one revolution of the lens module, if the rotational speed of the lens module is in the initial stage; and
applying a second operating pressure onto the glue to dispense the glue onto the spacer during one revolution of the lens module, the second operating pressure being different from the first operating pressure, if the rotational speed of the lens module is in the subsequent steady stage.

Other advantages and novel features will become more apparent from the following detailed description of embodiments when taken in conjunction with the accompanying drawings.

### BRIEF DESCRIPTION OF THE DRAWINGS

Many aspects of the present dispensing process can be better understood with reference to the following drawings. The components in the drawings are not necessarily drawn to scale, the emphasis instead being placed upon clearly illustrating the principles of the present dispensing process. Moreover, in the drawings, like reference numerals designate corresponding parts throughout the several views.

FIG. 1 shows a stage of a dispensing process, in accordance with a preferred embodiment, a dispenser, a rotating platform and a lens module positioned on the rotary platform being provided;

FIG. 2 is a graph showing a relationship between operating pressure applied on glue and time in a rotary movement of the lens module of FIG. 1;

FIG. 3 is a graph showing a relationship between an operating pressure applied on glue and time in a rotary movement of the lens module of FIG. 1, in accordance with another preferred embodiment;

FIG. 4 is a graph showing a conventional relationship between a rotational speed of a lens module and time in a dispensing process; and

FIG. 5 is a graph showing a conventional relationship between an operating pressure applied on glue and time, associated with the relationship shown in FIG. 4.

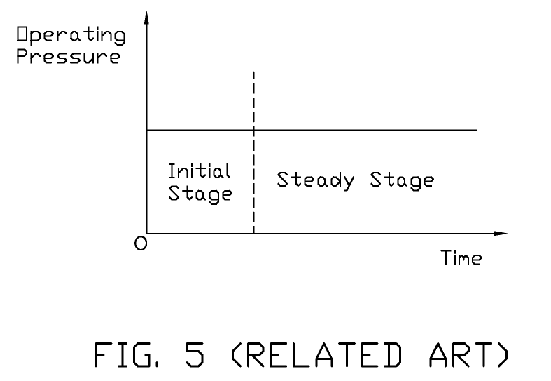

The exemplifications set out herein illustrate at least one preferred embodiment, in one form, and such exemplifications are not to be construed as limiting the scope of the present dispensing process in any manner.

### DETAILED DESCRIPTION

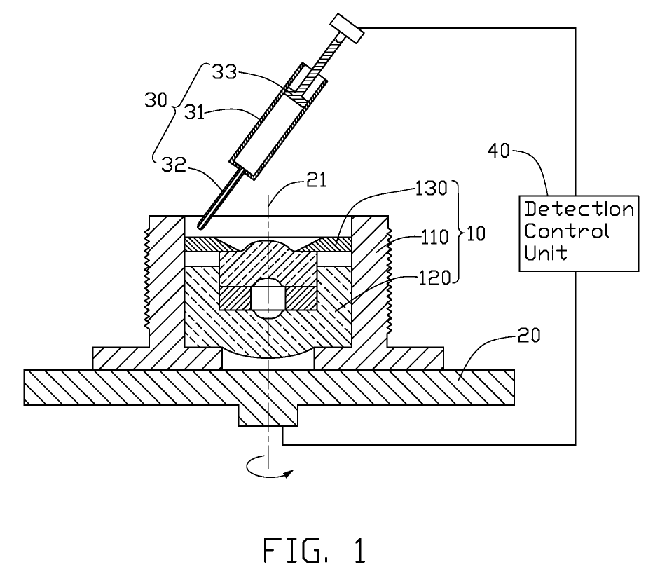

Referring to FIG. 1, a lens module 10, a rotating platform 20, a dispenser 30 for glue, adhesive or the like, and a detection control unit 40 are provided.

The lens module 10 acts as a pre-dispensing target and is positioned/loaded on the rotating platform 20. The lens module 10 includes a lens barrel 110, a lens group including lenses 120, and an annular spacer 130. The lens group and the spacer 130 are secured into the lens barrel along a central axis of the lens barrel 110 (i.e., generally an optical axis of the lens module 10), in that order from an object side to an image side of the lens module 10. The spacer 130 has an annular pre-dispensing side opposite the lens group and defines an annular pre-dispensing region for receiving glue on the pre-dispensing side. The spacer 130 generally defines a central axis being substantially coaxial with a central axis of the lens barrel 110.

The rotating platform 20 is capable of being driven to rotate around the central axis of the lens barrel 110 and thus the lens module 10 positioned thereon can undergo a simultaneous rotary movement.

The dispenser 30 for glue includes a container 31, a nozzle 32, and a pressure-applying member 33. The container 31 is configured for supplying a glue. The nozzle 32 is in fluid communication with the container 31. The pressure-applying member 33 is slidably fitted into the container 31 and configured (i.e., structured and arranged) for applying a pressure on the glue contained in the container 31 in order to force the glue to flow out from the nozzle 32.

The detection control unit 40 is configured for detecting a variation of a rotational speed of the rotary movement of the rotating platform 20 in operation and then producing/generating a control signal to give the pressure-applying member 33 a matching operating pressure, in order to make the glue to flow out from the nozzle 32 with a suitable speed of flow. The control signal is in conjunction with the detected variation of the rotational speed.

When the lens module 30 is placed/loaded on the rotating platform 20, a glue dispensing process, associated with a preferred embodiment, further includes the following steps. Such associated steps will be described in detail with reference to FIGS. 1 through 3.

The nozzle 32 of the dispenser 30 is positioned adjacent to the annular pre-dispensing region of the spacer 130 received in the lens barrel 110.

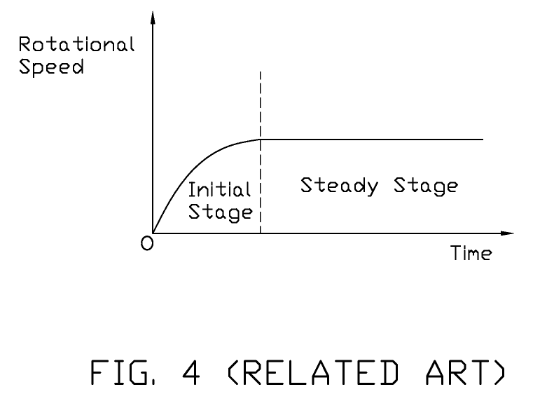

The rotating platform 20 having the lens module 30 loaded thereon is driven to rotate around the central axis of the lens barrel 110 (i.e., generally about the optical axis 21 of the lens module 10). Simultaneously, the lens module 10 is driven to rotate around the central axis of the lens barrel 110 by the rotating platform 20. Generally, the rotary movement of the rotating platform 20 (i.e., the rotary movement of the lens module 10) has two stages, one is an initial stage and another is a subsequent steady stage. A relationship between a rotational speed of the rotary movement and time is similar to that shown in FIG. 4. In particular, in the initial stage, the rotational speed of the lens module 10 is variable, e.g., the rotational speed gradually increases from the start of the rotary movement; in the subsequent steady stage, the rotational speed of the lens module 10 is substantially constant.

A variation of the rotational speed of the lens module 10 is detected via the detection control unit 40. The detection control unit 40 then acquires the stage of the rotary movement of the lens module 10 based on the detected variation of the rotational speed, and produces/generates a control signal to give the pressure-applying member 33 a corresponding operating pressure. The importance of the operating pressure and the variation of the rotational speed will be described in the following two examples in detail.

### EXAMPLE 1

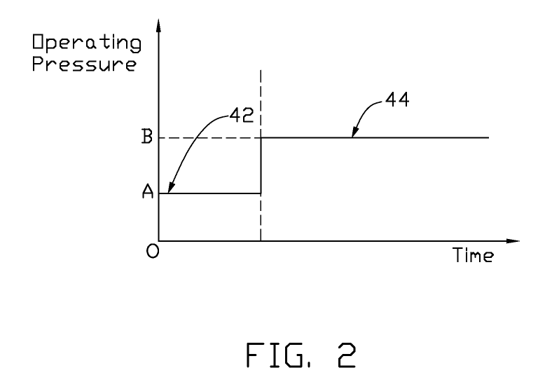

Referring to FIG. 2, in one aspect, if the variation of the rotational speed detected by the detection control unit 40 is variable, the detection control unit 40 will acquire the rotary movement of the lens module 10 being in the initial stage and give the pressure-applying member 33 a first operating pressure 42. The first operating pressure 42 has a value of A, as shown in FIG. 2.

In another aspect, if the variation of the rotational speed detected by the detection control unit 40 is substantially constant, the detection control unit 40 will acquire the rotary movement of the lens module 10 being in the steady stage and give the pressure-applying member 33 a second operating pressure 44. The second operating pressure 44 has a value of B higher than that of the first operating pressure 42.

That is, the operating pressure, e.g., the first operating pressure 42 and the second operating pressure 44, in the example 1, is in compensation with the variation of the rotational speed of the rotary movement of the lens module 10, i.e., the stages of the rotary movement of the lens module 10. The relevancy of the operating pressure and the variation of the rotational speed will effectively facilitate the formation of a uniform boding layer on the pre-dispending side of the spacer 130.

### EXAMPLE 2

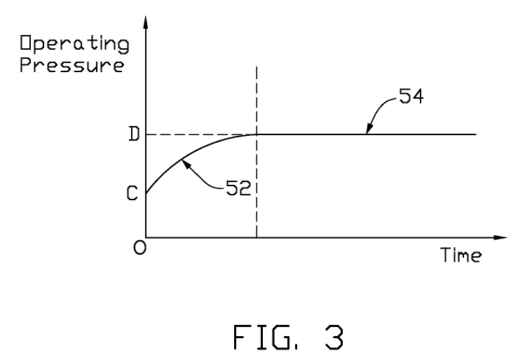

Referring to FIG. 3, in one aspect, if the variation of the rotational speed detected by the detection control unit 40 is variable, the detection control unit 40 will acquire the rotary movement of the lens module 10 being in the initial stage and give the pressure-applying member 33 a first operating pressure 52. As shown in FIG. 3, the first operating pressure 52 gradually increases, corresponding to the gradually increased rotational speed in the initial stage.

As an illustrated purpose, if a relationship between the rotational speed of the lens module 10 and the time, in the initial stage, satisfies the condition (1): V²=m×t, (m>0), where V represents the rotational speed of the lens module 10, t represents the time calculated from the start of the rotary movement of the lens module 10, and m is a constant integer. Correspondingly, a relationship between the first operating pressure 52 and the time can satisfy the condition (2): (P−C)²=n×t, (n>0); where P represents a value of the first operating pressure 52, C is the initial value of the first operating pressure 52, t represents the time calculated from the start of the rotary movement of the lens module 10, and n is a constant integer. That is, a variation trend of the first operating pressure, in the initial stage, is similar to a variation trend of the rotational speed of the lens module 10, which will effectively facilitate the formation of a uniform bonding layer (not shown) formed of glue on the pre-dispensing region of the spacer 130.

In another aspect, if the variation of the rotational speed is detected by the detection control unit 40 is substantially constant, the detection control unit 40 will acquire the rotary movement of the lens module 10 being in the steady stage and set the pressure-applying member 33 with a second operating pressure 54. The second operating pressure 54 has a value of D higher than that of the first operating pressure 42.

That is, the operating pressure, e.g., the first operating pressure 52 and the second operating pressure 54, in the example 2, compensates for the variation of the rotational speed of the rotary movement of the lens module 10. The first operating pressure 52 has a variation trend similar to that of the rotational speed in the initial stage. The relevancy of the operating pressure and the variation of the rotational speed will further effectively facilitate the formation of a uniform boding layer on the side of the spacer 130.

Glue contained in the container 31 of the dispenser 30 is forced to flow through the nozzle 32 under an operating pressure (i.e., the first operating pressure 42, 52, or the second operating pressure 44, 54) set by the detection control unit 40. The glue will flow out from the nozzle 32 with a flow rate corresponding to the operating pressure, and is substantially uniformly dispensed/distributed over the side of the spacer 130 (hereinafter, this step will be named as a dispensing step). Usually, the larger the operating pressure applied on the glue is, the larger the speed of flow of the glue tends to be. As such, a uniform bonding layer (not shown) formed by the glue can be formed on the side of the spacer 130. Thereafter, a filter, e.g., an IR cut filter can be bonded with spacer 130 together via the bonding layer, thus assembling the lens module 10.

Generally, regarding a target, such as a lens module 10, after the lens module 10 has been rotated through one circle, the above-mentioned glue dispensing step and the rotary movement of the lens module 10 are simultaneously stopped. It is understood that after the lens module 10 has been rotated through one circle, the above-mentioned glue dispensing step can be stopped before the rotary movement is stopped. As an illustrated purpose, if a diameter of the lens barrel 110 of the lens module 10 is about 9 millimeters, a taken time for the lens module 10 to rotate through one circle is about 5 seconds, wherein about 0.5 second is taken up by the initial stage.

Because the operating pressures of the pressure-applying member 33 applied on the glue are matched with the stages (i.e., generally the rotational speeds) of the rotary movement of the lens module 10 (i.e., a pre-dispending target), it overcomes the drawback of conventional dispensing process with a fixed operating pressure. Accordingly, a uniform bonding layer can be readily formed on the pre-dispensing side of the spacer 130.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the present invention.

What is claimed is:

1. A glue dispensing process, comprising the steps of:
providing a lens module including a lens barrel and an annular spacer received in the lens barrel;
rotating the lens module around a central axis of the lens barrel in such a manner that a rotational speed of the lens module is variable in an initial stage and is essentially constant in a subsequent steady stage;
detecting whether the rotational speed of the lens module is in the initial stage or the subsequent steady stage;
applying a first operating pressure onto the glue to dispense the glue onto the spacer during one revolution of the lens module, if the rotational speed of the lens module is in the initial stage; and
applying a second operating pressure onto the glue to dispense the glue onto the spacer during one revolution of the lens module, the second operating pressure being different from the first operating pressure, if the rotational speed of the lens module is in the subsequent steady stage.

2. The dispensing process of claim 1, wherein the rotational speed of the lens module is gradually increased in the initial stage.

3. The dispensing process of claim 2, wherein the first operating pressure is essentially constant in the initial stage, the second operating pressure is essentially constant in the subsequent steady stage, and the first operating pressure is less than the second operating pressure.

4. The dispensing process of claim 2, wherein the first operating pressure is gradually increased in the initial stage, the second operating pressure is substantially constant, and the first operating pressure has a maximum value not higher than the second operating pressure.

5. The dispensing process of claim 1, further comprising the steps of stopping rotating the lens module, and stopping dispensing the glue onto the spacer.

6. The dispensing process of claim 5, wherein the step of stopping rotating the lens module, and the step of stopping dispensing the glue onto the spacer are carried out simultaneously.

7. A glue dispensing process, comprising the steps of:
providing a pre-dispensing target, the pre-dispensing target having an annular region for receiving glue;
rotating the target around a central axis of the annular region in a manner such that a rotational speed of the target is variable in an initial stage and is essentially constant in a subsequent steady stage;
dispensing the glue with a first flow rate, onto the annular pre-dispensing region during one revolution of the target, if the rotational speed of the target is in the initial stage; and
dispensing the glue with a second flow rate different from the first flow rate, onto the annular pre-dispensing region during one revolution of the pre-dispensing target, if the rotational speed of the target is in the subsequent steady stage.

8. The glue dispensing process of claim 7, further comprising a step of detecting whether the rotational speed of the pre-dispensing target is in the initial stage or the subsequent steady stage.

9. The dispensing process of claim 7, wherein the rotational speed of the pre-dispensing target is gradually increased in the initial stage, the first speed of flow is essentially constant in the initial stage, the second flow rate is essentially constant in the subsequent steady stage, and the first flow rate is less than the second flow rate.

10. The dispensing process of claim 7, wherein the rotational speed of the pre-dispensing target is gradually increased in the initial stage, the first speed of flow is gradually increased in the initial stage, the second speed of flow is substantially constant, and the first speed of flow has a maximum value not higher than the second speed of flow.

11. The dispensing process of claim 7, further comprising the steps of stopping rotating the target, and stopping dispensing the glue onto the annular region.

12. The dispensing process of claim 11, wherein the step of stopping rotating the target, and the step of stopping dispensing the glue onto the annular region are carried out simultaneously.

13. A dispenser assembly used for dispensing a fluid onto a target, comprising:
a container configured for supplying a fluid;
at least a nozzle in fluid communication with the container and configured for dispensing the fluid onto the target;
a pressure-applying member configured for applying a pressure on the fluid contained in the container; and
a detection control unit configured for detecting a rotational speed of the target in a dispensing process, and thus setting the pressure applied on the fluid via the pressure-applying member based on the detected rotational speed.

14. The dispenser assembly of claim 13, further comprising a rotating platform, the rotating platform being rotatable and being configured for loading the target thereon.

15. The dispenser assembly of claim 13, wherein the pressure-applying member is slidably fitted in the container.
